(19) United States
(12) Patent Application Publication
(10) Pub. No.: US 2025/0174475 A1
(43) Pub. Date: May 29, 2025

(54) SUPPORT SLEEVE FOR SUPPORTING A PROCESS VESSEL AND ASSOCIATED SEMICONDUCTOR PROCESSING FURNACES

(71) Applicant: ASM IP Holding B.V., Almere (NL)

(72) Inventors: Theodorus G.M. Oosterlaken, Oudewater (NL); Marco Dirkmaat, Woudenberg (NL); Klaas Boonstra, Hilversum (NL); Herbert Terhorst, Amersfoort (NL)

(21) Appl. No.: 18/963,382

(22) Filed: Nov. 27, 2024

Related U.S. Application Data
(60) Provisional application No. 63/603,937, filed on Nov. 29, 2023.

(51) Int. Cl. H01L 21/673; H01L 21/67

(52) U.S. Cl. CPC H01L 21/67383; H01L 21/67017

(57) ABSTRACT

Support sleeves and semiconductor processing furnaces including such support sleeves are disclosed. The support sleeves disclosed include a single support surface for supporting a process vessel within a semiconductor processing furnace. The support sleeves disclosed also include a number of internal gas channels configured for forming a gas seal between the support sleeve and a process vessel supported on the support sleeve.

### CROSS-REFERENCE TO RELATED APPLICATION(S)

This Application claims the benefit of U.S. Provisional Application 63/603,937 filed on Nov. 29, 2023, the entire contents of which are incorporated herein by reference.

### FIELD

The present disclosure generally relates to the field of semiconductor processing apparatus and systems, and to the field of device and integrated circuit manufacture. More particular, the present disclosure relates to a support sleeve for supporting a process vessel within a semiconductor processing furnace.

### BACKGROUND

Batch processing of semiconductor substrates is often performed in semiconductor processing furnaces. Such semiconductor processing furnaces are commonly employed for high temperature processes at temperatures above 1000° C., for example. Such semiconductor processing furnaces can include an internal process vessel which is supported within the furnace by a support structure. Such support structures commonly include multiple support surfaces which engage with the process vessel at various locations to support and position the process vessel within the semiconductor processing furnace.

However, the process vessel and the support structure are frequently fabricated from different materials having different thermal expansion coefficients. Therefore, the multiple contact interfaces between the process vessel and the support structure can come under increasing stress during thermal cycling of the furnace. Such stresses can result in damage to one or more of the process vessel and the support structure and the formation of unwanted particulates. Accordingly, improved support structures are desirable to reduce particle formation as well as to prevent any particles that do form from entering the reaction space within the process vessel.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

In accordance with examples of the disclosure a support sleeve for supporting a process vessel comprising a ledge protruding from an outer surface of the process vessel and a base surface for sealing the process vessel in a furnace for semiconductor processing is provided. In such examples, the support sleeve includes an interior surface and an exterior surface, a top surface constructed and arranged to engage with and support the process vessel at the ledge, and a bottom surface. In such examples, the support vessel includes a shoulder including an intermediate surface disposed between the top surface and the bottom surface. In such examples the intermediate surface extends from the interior surface and is constructed and arranged to form a portion of a diffusion barrier channel between the intermediate surface of the shoulder and the base surface of the process vessel.

In some embodiments, the support sleeve is fabricated from a single piece of material.

In some embodiments, the top surface of the support sleeve is an annular top surface extending between the exterior surface of the support sleeve and the interior surface of the support sleeve.

In some embodiments, the shoulder is an annular shoulder. In such embodiments, the intermediate surface is an annular surface.

In some embodiments, the support sleeve further includes a circumferential channel disposed within the support sleeve and in fluid communication with a gas inlet channel.

In some embodiments the support also includes a plurality of feed channels disposed within the support sleeve, each feed channel having a first end in fluid communication with the circumferential channel and a second end in fluid communication with a gas injection aperture. In such embodiments, each of the gas injection apertures extend from the second end of the feed channel through the interior surface of the support sleeve.

In accordance with further examples of the disclosure, a support sleeve for supporting a process vessel is provided. In such examples, the support sleeve includes a hollow cylindrical core comprising an exterior surface, an interior surface, a bottom surface, and an annular top surface extending between the exterior surface and the interior surface, the annular top surface constructed and arranged as a single support surface to support the process vessel during operation. In such examples the support sleeve includes an annular shoulder extending inwardly from a lower portion of the interior surface, the annular shoulder having an intermediate surface constructed and arranged to form a portion of a diffusion barrier channel between the intermediate surface of the annular shoulder and a base surface of the process vessel when supported on the annular top surface. In such examples the support sleeve includes a circumferential channel disposed within the single piece support sleeve and in fluid communication with a gas inlet port extending outwardly from the exterior surface. In such examples the support sleeve includes a plurality of feed channels disposed within the hollow cylindrical core, each feed channel having a first end in fluid communication with the circumferential channel and a second end in fluid communication with a gas injection aperture. In such examples, each of the gas injection apertures extend from the second end of the feed channel through the interior surface of the single piece support sleeve.

In accordance with additional examples of the disclosure, a semiconductor processing furnace is provided. In such examples the semiconductor processing furnace includes a support sleeve including an interior surface, an exterior surface, a top surface, a bottom surface, and an intermediate surface disposed between the top surface and the bottom surface, the intermediate surface extending inwardly from the interior surface of the support sleeve. In such examples the semiconductor processing furnace include a process vessel overlying the support sleeve, the process vessel including a base surface and a ledge protruding from an outer surface of the process vessel. In such examples, the underside of the ledge contacts the top surface of the support sleeve and the base surface of the process vessel and the intermediate surface of the support sleeve define a portion of a diffusion barrier channel for gas sealing the support sleeve from the process vessel.

In some embodiments, the support sleeve has a hollow cylindrical core.

In some embodiments, the top surface is an annular top surface. In such examples, the intermediate surface is an upper surface of an annular shoulder. In such examples, the intermediate surface of the support sleeve is a single support surface for supporting the process vessel thereon.

In some embodiments, the support sleeve of the semiconductor processing furnace includes a circumferential channel disposed within the support sleeve and in fluid communication with a gas inlet channel.

In some embodiments, the support sleeve of the semiconductor processing furnace includes a plurality of feed channels disposed within the support sleeve, each feed channel having a first end in fluid communication with the circumferential channel and a second end in fluid communication with a gas injection aperture. In such examples, each of the gas injection apertures extend from the second end of the feed channel through the interior surface of the support sleeve.

In some embodiments, the semiconductor processing furnace includes a first portion of a diffusion barrier channel including a channel formed between the interior surface of the support sleeve and the outer surface of the process vessel.

In some embodiments, the semiconductor processing furnace includes a second portion of a diffusion barrier channel comprises a channel formed between the base surface of the process vessel and the intermediate surface of the support sleeve.

In some embodiments the support vessel of the semiconductor processing furnace is fabricated from a single piece of material.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 illustrates a semiconductor processing furnace in accordance with one or more embodiments of the disclosure.

FIG. 2 illustrates a cross sectional view of a support sleeve in accordance with one or more embodiments of the disclosure.

FIG. 3 illustrates a plan view of a support sleeve in accordance with one or more embodiments of the disclosure.

FIG. 4 illustrates a prospective view of a support sleeve in accordance with one or more embodiments of the disclosure.

FIG. 5 illustrates a further prospective view of a support sleeve in accordance with one or more embodiments of the disclosure.

FIG. 6 illustrates a cross sectional view of a process vessel supported on a support sleeve in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of apparatus and systems provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted. By way of examples, a substrate can include semiconductor material. The semiconductor material can include or be used to form one or more of a source, drain, or channel region of a device. The substrate can further include an interlayer dielectric (e.g., silicon oxide) and/or a high dielectric constant material layer overlying the semiconductor material. In this context, high dielectric constant material (or high k dielectric material) is a material having a dielectric constant greater than the dielectric constant of silicon dioxide.

Semiconductor processing furnaces commonly employ an internal process vessel in which the various semiconductor fabrication processes are performed. The process vessel is frequently fabricated from silicon carbide (SiC) due to it being to withstand the high temperatures and thermal cycling operations performed with the furnace.

The process vessel is commonly supported within the furnace by a support structure, referred to herein as a support sleeve. Prior support sleeves frequently include multiple support surfaces configured for engaging with and supporting the process vessel. However, the support sleeve is frequently fabricated from one or more materials with a lower thermal conductivity than the silicon carbide process vessel to prevent heat conduction away from the process vessel. This difference in materials can result in a difference between the thermal expansion coefficients of the process vessel and support sleeve leading to high stresses at the multiple contacting interfaces between the process vessel and the support sleeve during thermal cycling of the semiconductor processing furnace. This stress can generate particles which can have a detrimental effect not only on the processes being performed within the process vessel but can also result in more frequent maintenance in order to maintain operation of the semiconductor processing furnace. In addition, one or more seals are commonly employed to prevent gas exchange between the process vessel and the external environment. Frequently, such a seal takes the form of a physical seal. For example, the seal can be formed by the contact surfaces of the process vessel and the underlying support structure. However, such physical seals may not be completely gas tight and as result may allow some gas leakage into and/or out of the process vessel.

Therefore, the various embodiments of the present disclosure provide a support sleeve with a single support surface for supporting the process vessel within the furnace. Employing a single support surface reduces the number of interfaces between the support sleeve and the process vessel resulting in a reduction in particle formation and less need for frequent furnace maintenance. In addition, the various embodiments of the present disclosure provide a support sleeve including a number of integrated gas channels able to provide a uniform gas flow directed inwardly from an inner surface of the support sleeve, where “inwardly” as used herein can refer to a direction towards the center of the support sleeve, i.e., towards a process vessel. Such a gas flow from the support sleeve creates a diffusion barrier between the process vessel and the support sleeve which creates a non-physical seal (i.e., a gas seal). The use of such a gas seal removes the requirement for a completely leak tight physical seal between the process vessel and the support sleeve which further enables the use of a support sleeve with a single support surface.

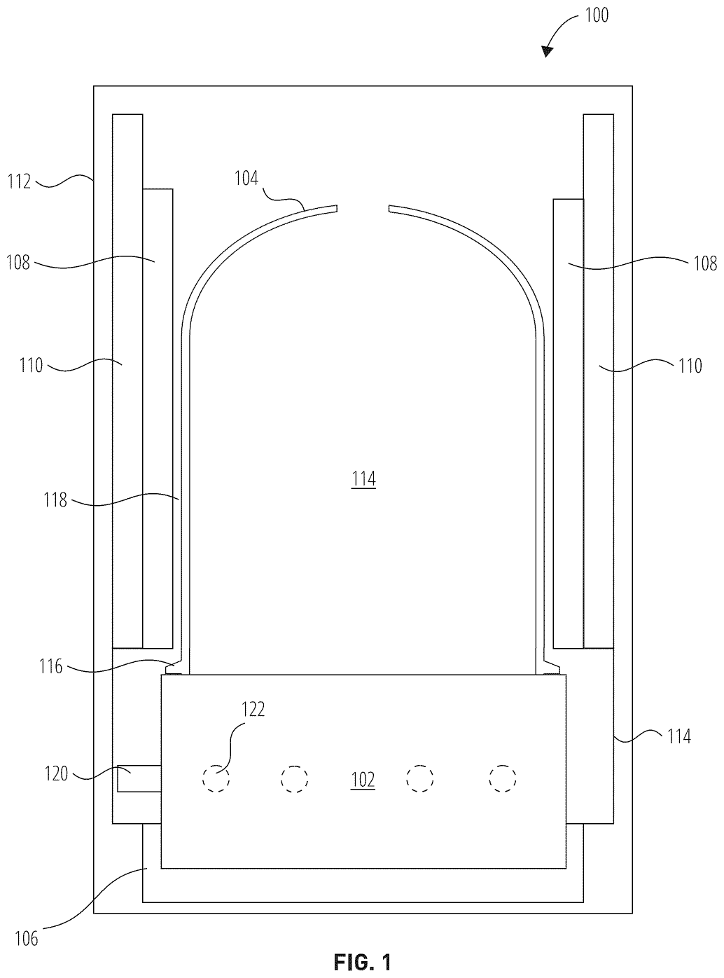

Turning now to the figures, FIG. 1 is a simplified schematic of an semiconductor processing furnace 100, including a support sleeve 102 in accordance with examples of the disclosure. The semiconductor processing furnace 100 includes a process vessel 104 supported by the support sleeve 102, which in turn is supported by flanges 106. The process vessel 104 supported by the support sleeve 102 is heated by heaters 108, and an isolation material 110 is disposed between the heaters 108 and an outer shell 112. The process area, or reaction space 114, in which process gases can interact with substrates (not shown) during semiconductor fabrication processes, is delimited by the process vessel 104 (which is open at its bottom and top ends and is inside the outer shell 112.

As illustrated in FIG. 1 the process vessel 104 includes a ledge 116 protruding from an outer surface 118 of the process vessel 104. In accordance with examples of the disclosure, the interface between the ledge 116 and a top surface of the support sleeve 102 is the single support interface between the processing process vessel 104 and the support sleeve 102, as described in greater detail below. In addition, the support sleeve 102 includes a gas inlet port in fluid communication with a plurality of gas injection apertures 122 for forming a diffusion barrier (i.e., a gas seal) between the process vessel 104 and the support sleeve 102, as described in greater detail below.

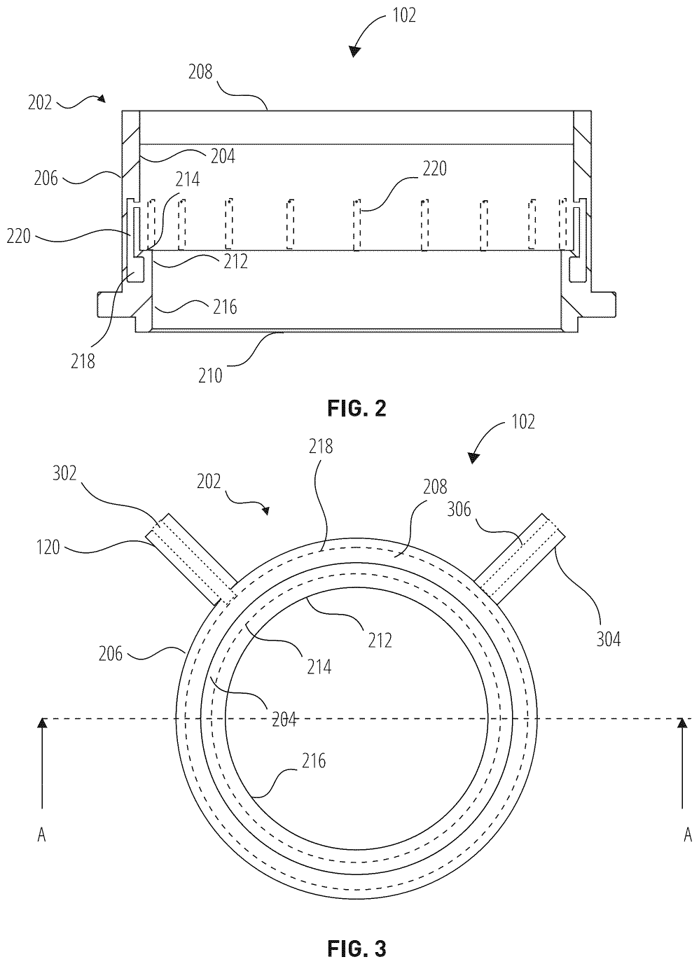

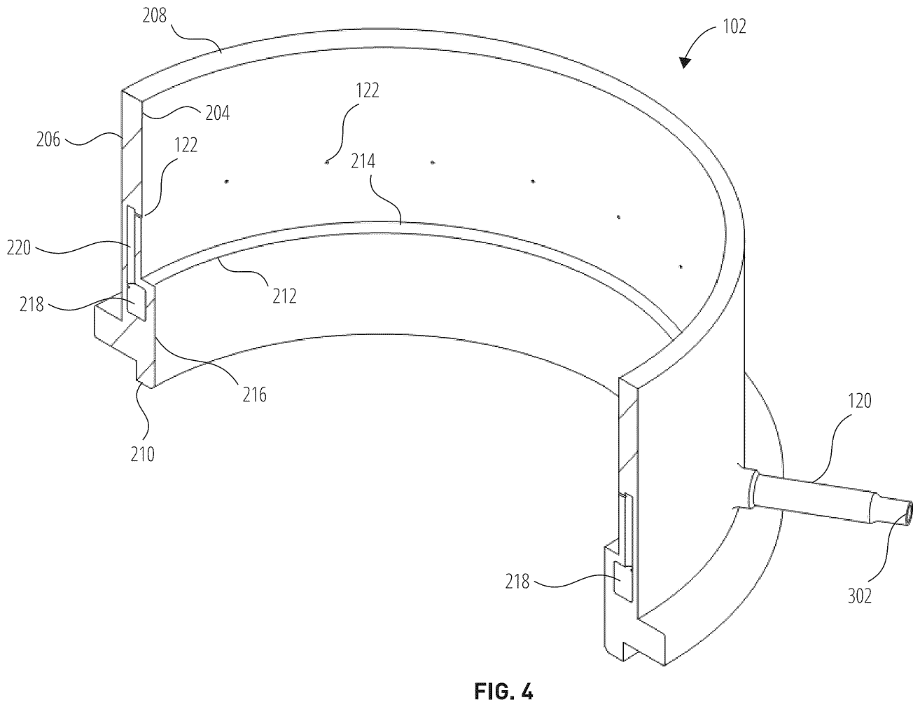

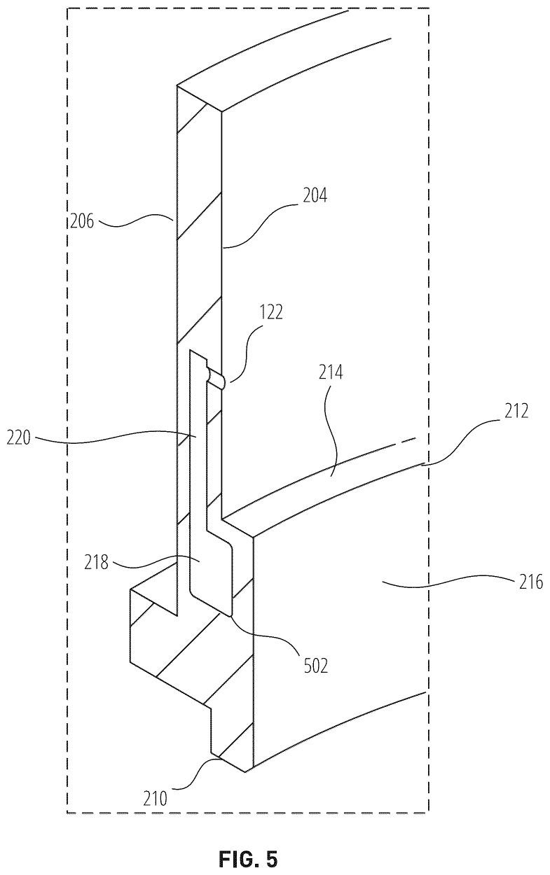

FIG. 2, FIG. 3, FIG. 4, and FIG. 5 are illustrations of various views of the support sleeves of the present disclosure. FIG. 2 illustrates a cross-section view through an exemplary support sleeve in accordance with embodiments of the disclosure. FIG. 3 illustrates a plan view of an exemplary support sleeve in accordance embodiments of the disclosure. FIG. 4 illustrates a prospective view of an exemplary support sleeve including a partial cut-way in accordance with embodiments of the disclosure and FIG. 5 illustrates a magnified view of a portion of FIG. 4 in accordance with embodiments of the disclosure.

In greater detail and with reference to FIGS. 2-5, the support sleeve 102 comprises an interior surface 204, an exterior surface 206, a bottom surface 210, and a top surface 208. In such examples, the surfaces 204, 206, 208, and 210 define the core of the support sleeve 102. In some embodiments, the core of the support sleeve 102 comprises a hollow cylinder, i.e., the support sleeve 102 comprises a hollow cylindrical core. In some embodiments, the support sleeve 102 is fabricated from a single piece of material. In such embodiments, the support sleeve 102 is a single piece support sleeve. In some embodiments, the support sleeve 102 is fabricated from two or more pieces of material. In such embodiments, the support sleeve 102 is a multiple piece support sleeve. In some embodiments, the support sleeve 102 is fabricated from quartz. In some embodiments, the support sleeve 102 is fabricated from a single piece of quartz. In some embodiments, the support sleeve 102 is fabricated from silicon carbide. In some embodiments, the support sleeve 102 is fabricated from a single piece of silicon carbide. In examples where the support sleeve is a multiple piece support sleeve, the two of more pieces of material used to fabricate the multiple piece can each include quartz and/or silicon carbide.

In accordance with examples of the disclosure, the support sleeve 102 includes the top surface 208. In such examples, the top surface 208 of the support sleeve 102 is constructed and arranged to engage with and support a process vessel, as described in more detail below. In accordance with examples of the disclosure, the top surface 208 is a single support surface for supporting a process vessel thereon. In such examples, the support sleeve 102 does not include any additional surfaces in contact with the process vessel. In some embodiments the top surface 208 comprises an annular top surface extending between the exterior surface 206 and the interior surface 204. In such embodiments, the annular top surface is constructed and arranged to support a process vessel within a semiconductor processing furnace.

In accordance with examples of the disclosure, the support sleeve 102 includes a shoulder 212 extending inwardly (i.e., towards the center of the support sleeve) from the interior surface 204 of the support sleeve. In such examples, the shoulder 212 includes an intermediate surface 214 disposed between the top surface 208 and the bottom surface 210. In such examples, the intermediate surface 214 is the upper surface of the shoulder 212 and extends inwardly from the interior surface 204 of the support sleeve 102. In some embodiments, the shoulder 212 is an annular shoulder extending inwardly from a lower portion of the interior surface 204. In such examples, the annular shoulder is concentric to the annular top surface, with the annular shoulder and the annular top surface having the same center point (as illustrated in FIG. 3). In some embodiments, the shoulder 212 and particularly the intermediate surface 214 of the shoulder 212 is constructed and arranged to form an aperture between the intermediate surface 214 and a base surface of a process vessel, as described in greater detail below.

The support sleeves of the present disclosure also include integrated gas channels for creating a diffusion barrier between the process vessel and the support sleeve. In brief, the support sleeves of the present disclosure include a gas inlet port including a gas inlet channel for injecting a sealing gas into a circumferential channel disposed with the support sleeve. The internal circumferential channel distributes the sealing gas around the entire circumference of the support sleeve. The sealing gas flows from the circumferential channel into a plurality of feed channels distributed around the support sleeve and in turn the feed channels convey the sealing gas to a plurality of gas injection apertures which extend into and through the interior surface of the support sleeve. The plurality of gas injection apertures enables the distribution of the sealing gas into the hollow center of the support sleeve to form a diffusion barrier with a process vessel. The following describes the elements of the support sleeves of the present disclosure that enable the creation of the diffusion barrier in greater detail.

In accordance with examples of the disclosure, the support sleeve 102 includes a gas inlet port 120 (see FIG. 3 and FIG. 4). In such examples the gas inlet port 120 extends outwardly (i.e., away from the center of the support sleeve) from the exterior surface 206 of the support sleeve. The gas inlet port 120 includes a gas inlet channel 302 disposed within, as illustrated in FIG. 3 by a short dashed line to indicate the gas inlet channel 302 is within the volume of the core of the support sleeve 102. In some embodiments, the gas inlet channel 302 is in fluid communication with a circumferential channel disposed within the support sleeve, as described in more detail below. The gas inlet port 120 is employed to introduce one or more sealing gases into the support sleeve 102. In some embodiments the support sleeve 102 also includes an exhaust port 304 including an exhaust channel 306 employed for the evacuation of gases from the support sleeve.

In accordance with examples of the disclosure, the support sleeve 102 includes a circumferential channel 218 disposed with the support sleeve 102 (see FIG. 3 and FIG. 4). In such embodiments, the circumferential channel 218 is in fluid communication with the gas inlet channel 302 of the gas inlet port 120 to enable a sealing gas to be introduced from an external source (not shown), through the gas inlet channel 302 and subsequently into the circumferential channel 218. The circumferential channel 218 extends radially around interior of the support sleeve to enable the even distribution of the sealing gas around the support sleeve.

In accordance with examples of the disclosure, the circumferential channel 218 is formed within the hollow cylindrical core of the support sleeve 102, as illustrated in FIG. 3 by a dashed line to indicted the circumferential channel 218 is with the volume of the core of the support sleeve 102 and as illustrated in the cut-away section of FIG. 4. In some embodiments, the circumferential channel 218 is disposed between the exterior surface 206 and the interior surface 204. In such examples, the circumferential channel 218 can be disposed between the exterior surface 206 and a shoulder side surface 216. In some embodiments, the circumferential channel 218 is disposed between the bottom surface 210 of the support sleeve and the intermediate surface 214 of the shoulder 212.

In accordance with examples of the disclosure, the circumferential channel 218 has a substantially rectangular profile, as illustrated by the channel profile 502 in FIG. 5. In such embodiments, the circumferential channel 218 has a channel width between 5 mm and 20 mm and a channel height between 10 mm and 30 mm. The circumferential channel 218 is not limited to a rectangular profile, for example, the channel profile can be a square profile or a circular profile.

In accordance with examples of the disclosure, the support sleeve 102 further includes a plurality of feed channels 220 disposed within the support sleeve 102. In such embodiments, the plurality of feed channels 220 are in fluid communication with the circumferential channel 218 to enable a sealing gas to be introduced from an external source (not shown), through the gas inlet channel 302, into the circumferential channel 218, and subsequently into the plurality of feed channels 220.

In accordance with examples of the disclosure, the plurality of feed channels 220 are formed within the hollow cylindrical core of the support sleeve 102, as illustrated in FIG. 2 by a dashed line to indicted the plurality of feed channels 220 are within the volume of the core of the support sleeve 102 and as illustrated in the cut-away section of FIG. 4. In some embodiments, the pluralities of feed channels 220 are disposed between the exterior surface 206 and the interior surface 204. In some embodiments, the plurality of feed channels 220 are orientated perpendicular to the top surface 208 of the support sleeve 102. In some embodiments, the feed channels 220 are orientated parallel to both the exterior surface 206 and the interior surface 204 of the support sleeve 102. In such embodiments, the feed channels 220 are vertical feed channels. In some embodiments, the plurality of feed channels 220 are equally spaced and distributed in a spaced-apart relationship radially within the hollow cylindrical core of the support sleeve around the interior surface 204. In some embodiments, the feed channels 220 have a circular profile. In such embodiments, the plurality of feed channels 220 have a diameter between 2 mm and 5 mm. In some embodiments the feed channels 220 have a length between 20 mm and 80 mm.

In accordance with examples of the disclosure, the support sleeve 102 further includes a plurality of gas injection apertures 122 disposed within the support sleeve 102. In such embodiments, each of plurality of gas injection apertures 122 are in fluid communication with a gas feed channel 220 to enable a sealing gas to be introduced from an external source (not shown), through the gas inlet channel 302, into the circumferential channel 218, into the feed channels 220, and into the gas injection apertures 122. In such examples, each of feed channels 220 have a first end in fluid communication with the circumferential channel 218 and a second end in fluid connection with a gas injection aperture 122.

In accordance with examples of the disclosure, each of the plurality of gas injection apertures 122 extend from a feed channel to and through the interior surface 204 of the support sleeve 102, as illustrated in FIG. 4 for example. In other words, the gas injection apertures 122 provide a channel for the sealing gas to flow from the feed channels and out of the support sleeve through the interior surface of the support sleeve.

In accordance with examples of the disclosure, the plurality of gas injection apertures 122 are formed within the hollow cylindrical core of the support sleeve 102, as illustrated in FIG. 4 and FIG. 5. In some embodiments, the gas injection apertures 122 are disposed between the exterior surface 206 and the interior surface 204. In some embodiments, the gas injection apertures 122 are orientated parallel to the top surface 208 of the support sleeve 102. In some embodiments, the gas injection apertures 122 are orientated perpendicular to both the exterior surface 206 and the interior surface 204 of the support sleeve 102. In such embodiments, the gas injection apertures are horizontal gas injection apertures. In some embodiments, the plurality of gas injection apertures 122 are equally spaced and distributed in a spaced-apart relationship radially around the interior surface 204 of the support sleeve 102. In some embodiments, the plurality of gas injection apertures 122 have a circular profile. In such embodiments, the gas injection apertures 122 have a diameter between 1 mm and 3 mm.

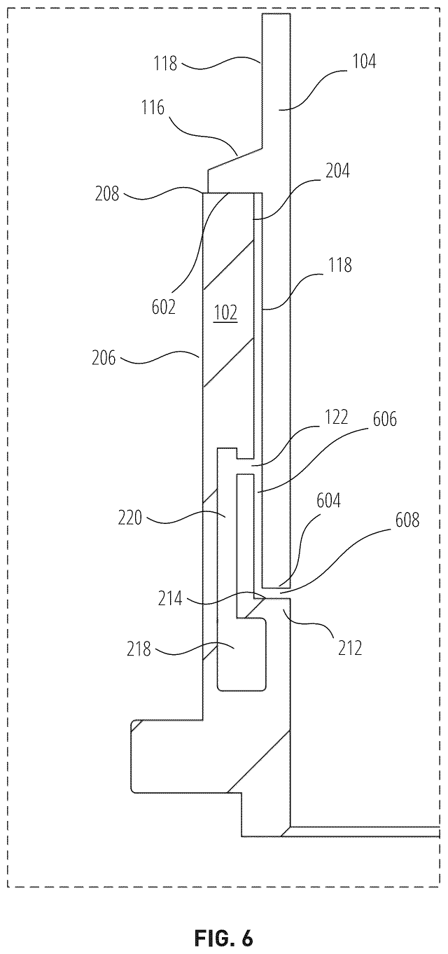

The embodiments of the present disclosure also include semiconductor processing furnaces including the support sleeves as described in detail above. To better illustrate the embodiments of the disclosure relating to semiconductor processing furnaces and the configuration of the process vessel in relation to the support sleeve FIG. 6 illustrates an expanded cross-sectional view of the process vessel 104 supported on the support sleeve 102.

In accordance with examples of the disclosure and with reference to FIG. 6, the process vessel 104 includes a ledge 116 protruding from an outer surface 118 of the process vessel 104. In such examples, the underside 602 of the ledge 116 contacts the top surface 208 of the support sleeve 102. In some embodiments, the top surface 208 of the support sleeve comprises an annular top surface and the underside 602 of the ledge 116 comprises an annular surface. In some embodiments, the process vessel 104 is supported by a single surface of the support sleeve 102, i.e., a single support surface. In such examples, the single support surface comprises the top surface 208 of the support sleeve 102. In such examples, the single support surface supports the process vessel 104 at the underside 602 of the ledge 116 which protrudes from the outer surface 118 of the process vessel 104. In such examples, the process vessel 104 is not supported by any additional surfaces of the support sleeve 102.

In accordance with additional examples of the disclosure and with reference to FIG. 6, the process vessel 104 includes a base surface 604. In such examples, the base surface 604 comprises the bottom or lowest part of the process vessel 104. As illustrated in FIG. 6 the base surface 604 of the process vessel 104 is not supported by the support sleeve 102. Instead, the base surface 604 is separated from the intermediate surface 214 of the support sleeve 102 by a predetermined distance, e.g., a vertical separation is maintained between the base surface 604 and the intermediate surface 214.

In more detail and with reference to FIG. 6, a sealing gas can be introduced into the support sleeve 102 and radially distributed around the support sleeve 102 by the circumferential channel 218. A plurality of feed channels 220 direct the barrier gas from the circumferential channel 218 to a plurality of gas injection apertures 122 to enable the flow of the sealing gas out of the interior of the support sleeve 102. In accordance with additional examples of the disclosure, a diffusion barrier channel can be formed between the support sleeve 102 and the process vessel 104 supported thereon. In such examples, a first portion of the diffusion barrier channel 606 comprises a channel formed between an interior surface 204 of the support sleeve 102 and the outer surface 118 of the process vessel 104. Further in such examples, a second portion of the diffusion barrier channel 608 comprises a channel formed between the base surface 604 of the process vessel 104 and the intermediate surface 214 of the support sleeve 102. The first portion of the diffusion barrier channel 606 and the second portion of the diffusion barrier channel 608 are in fluid communication with the plurality of gas injection apertures 122 (and likewise are fluid communication with the plurality of feed channels 220, the circumferential channel 218, and the gas inlet channel 302). Therefore, a sealing gas can be introduced into the support sleeve and injected out of the support sleeve 102 via the plurality of gas injection apertures 122 into a diffusion barrier channel comprising the first portion of the diffusion barrier channel 606 and the second portion of the diffusion barrier channel 608. In accordance with examples of the disclosure, the first portion of the diffusion barrier channel has a channel width between 1 mm and 5 mm. In accordance with further examples of the disclosure, the second portion of the diffusion barrier channel 608 has a channel width between 1 mm and 5 mm.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A support sleeve for supporting a process vessel comprising a ledge protruding from an outer surface of the process vessel and a base surface for sealing the process vessel in a furnace for semiconductor processing, the support sleeve comprising:
an interior surface and an exterior surface;
a top surface constructed and arranged to engage with and support the process vessel at the ledge;
a bottom surface; and
a shoulder including an intermediate surface disposed between the top surface and the bottom surface, the intermediate surface extending from the interior surface and constructed and arranged to form a portion of a diffusion barrier channel between the intermediate surface of the shoulder and the base surface of the process vessel.

2. The support sleeve of claim 1, wherein the support sleeve is fabricated from a single piece of material.

3. The support sleeve of claim 2, wherein the top surface is an annular top surface extending between the exterior surface of the support sleeve and the interior surface of the support sleeve.

4. The support sleeve of claim 3, wherein the shoulder comprises an annular shoulder.

5. The support sleeve of claim 4, wherein the intermediate surface comprises an annular surface.

6. The support sleeve of claim 1, further comprising a circumferential channel disposed within the support sleeve and in fluid communication with a gas inlet channel.

7. The support sleeve of claim 6, further comprising a plurality of feed channels disposed within the support sleeve, each feed channel having a first end in fluid communication with the circumferential channel and a second end in fluid communication with a gas injection aperture.

8. The support sleeve of claim 7, wherein each of the gas injection apertures extend from the second end of the feed channel through the interior surface of the support sleeve.

9. A support sleeve for supporting a process vessel comprising:
a hollow cylindrical core comprising an exterior surface, an interior surface, a bottom surface, and an annular top surface extending between the exterior surface and the interior surface, the annular top surface constructed and arranged as a single support surface to support the process vessel during operation;
an annular shoulder extending inwardly from a lower portion of the interior surface, the annular shoulder having an intermediate surface constructed and arranged to form a portion of a diffusion barrier channel between the intermediate surface of the annular shoulder and a base surface of the process vessel when supported on the annular top surface;
a circumferential channel disposed within the support sleeve and in fluid communication with a gas inlet port extending outwardly from the exterior surface; and
a plurality of feed channels disposed within the hollow cylindrical core, each feed channel having a first end in fluid communication with the circumferential channel and a second end in fluid communication with a gas injection aperture, wherein each of the gas injection apertures extend from the second end of the feed channel through the interior surface of the support sleeve,
wherein the support sleeve is fabricated from a single piece of material.

10. A semiconductor processing furnace, comprising:
a support sleeve comprising an interior surface, an exterior surface, a top surface, a bottom surface, and an intermediate surface disposed between the top surface and the bottom surface, the intermediate surface extending inwardly from the interior surface of the support sleeve; and
a process vessel overlying the support sleeve, the process vessel including a base surface and a ledge protruding from an outer surface of the process vessel, wherein an underside of the ledge contacts the top surface of the support sleeve and the base surface of the process vessel and the intermediate surface of the support sleeve define a portion of a diffusion barrier channel for gas sealing the support sleeve from the process vessel.

11. The semiconductor processing furnace of claim 10, wherein the support sleeve has a hollow cylindrical core.

12. The semiconductor processing furnace of claim 11, wherein the top surface is an annular top surface.

13. The semiconductor processing furnace of claim 12, wherein the intermediate surface is an upper surface of an annular shoulder.

14. The semiconductor processing furnace of claim 13, wherein the intermediate surface of the support sleeve is a single support surface for supporting the process vessel thereon.

15. The semiconductor processing furnace of claim 10, further comprising a circumferential channel disposed within the support sleeve and in fluid communication with a gas inlet channel.

16. The semiconductor processing furnace of claim 15, further comprising a plurality of feed channels disposed within the support sleeve, each feed channel having a first end in fluid communication with the circumferential channel and a second end in fluid communication with a gas injection aperture.

17. The semiconductor processing furnace of claim 16, wherein each of the gas injection apertures extend from the second end of the feed channel through the interior surface of the support sleeve.

18. The semiconductor processing furnace of claim 10, wherein a first portion of the diffusion barrier channel comprises a channel formed between the interior surface of the support sleeve and the outer surface of the process vessel.

19. The semiconductor processing furnace of claim 10, wherein a second portion of the diffusion barrier channel comprises a channel formed between the base surface of the process vessel and the intermediate surface of the support sleeve.

20. The semiconductor processing furnace of claim 10, wherein the support sleeve is fabricated from a single piece of material.
